(19) United States
(12) Patent Application Publication
(10) Pub. No.: US 2009/0184379 A1
(43) Pub. Date: Jul. 23, 2009

(54) SEMICONDUCTOR DEVICE HAVING DUMMY GATE PATTERN

(75) Inventor: Ken OTA, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/352,938

(22) Filed: Jan. 13, 2009

(30) Foreign Application Priority Data
Jan. 18, 2008 (JP) 2008-009887

(51) Int. Cl. H01L 27/088

(52) U.S. Cl. 257/401; 257/E27.06

(57) ABSTRACT

A semiconductor device includes a diffusion layer formed on a semiconductor substrate, a gate pattern arranged over the diffusion layer, and a dummy gate pattern arranged adjacently to the gate pattern with a constant gap over the diffusion layer. The gate pattern functions as a gate electrode of a MOS transistor while the dummy gate pattern does not function as the gate electrode. The dummy gate pattern is disconnected at a predetermined position in a gate width direction over the diffusion layer. By this stricture, the semiconductor is capable of achieving both an improvement in dimensional accuracy and a high-speed circuit operation.

### BACKGROUND OF THE INVENTION

1. Field of the Invention

The present invention relates to a semiconductor device having MOS transistors, and particularly relates to a semiconductor device provided with dummy gate patterns not functioning as gate electrodes in addition to gate patterns functioning as gate electrodes of MOS transistors

2. Description of Related Art

In recent years, as miniaturization of a semiconductor device has been progressed, it has been increasingly demanded to densely arrange gate patterns of a large number of MOS transistors. Since channel size which determines characteristics of a MOS transistor depends on dimension of a gate pattern arranged on an upper portion of the channel, it is desirable to keep required dimension based on a design rule of the gate pattern highly accurate. However, in manufacturing process of the semiconductor device, the dimension of the gate pattern varies due to a gap between adjacent gate patterns, and thereby the channel size of the MOS transistor varies, which causes circuit characteristics and yield to be deteriorated. In a case of 90 nm process, for example, the dimension varies by about 40 nm due to distribution of density of the adjacent gate patterns. If OPC (Optical Proximity Correction) technique effective for achieving highly accurate dimension is employed, variation amount of the dimension when the semiconductor device is exposed can be suppressed, however variation of etching amount cannot be appropriately controlled. Further, if a method for forming scattering bars having a fine line width is employed, the gap of gate patterns, which is not kept constant, causes that the number of the scattering bars changes and that level difference occurs, and thereby dimensional accuracy is partially deteriorated.

In order to avoid the above problems, it is required that the adjacent gate patterns are arranged with a constant gap in a vicinity of the channel. Therefore, a method is known in which a dummy gate pattern which does not actually function as a gate electrode is formed at a portion where a gate pattern as an actual gate electrode is not required. The dummy gate pattern has the same pattern shape as an actual gate pattern and arranged in the vicinity of the channel of the MOS transistor. The method of using the dummy gate pattern is disclosed in, for example, Patent References 1 to 3.

Patent Reference 1: Laid-open Japanese Patent Publication No. 2000-112114

Patent Reference 2: Laid-open Japanese Patent Publication No. 2002-208643

Patent Reference 3: Laid-open Japanese Patent Publication No. Hei 11-214634

FIG. 7 shows a layout example of the dummy gate pattern. In the layout example of FIG. 7, there are shown a diffusion layer 100, a gate pattern 101 formed over the diffusion layer 100, dummy gate patterns 102 formed over both sides of the diffusion layer 100, contacts 104 formed on a drain region D and a source region S of both sides inside diffusion layer 100. It is assumed in the example of FIG. 7 that another wiring extends on an upper portion between the drain and source regions D and S, and a state is shown in which the diffusion layer 100 is expanded at the side of the drain region D so that the position of the gate pattern 101 is deviated laterally. That is, gaps between the gate pattern 101 and the dummy gate patterns 102 are different from each other at drain and source sides in the vicinity of the channel gate, and thus a problem arises that uniform distribution of density is not obtained.

FIG. 8A shows another layout example of the dummy gate pattern. In the layout example of FIG. 8A, a dummy gate pattern 103 to which electricity is always supplied is formed in addition to the gate pattern 101 and the dummy gate patterns 102 as in FIG. 7 in order to avoid the problem of FIG. 7. That is, the dummy gate pattern 103 connected to a power supply voltage VDD is arranged between the gate pattern 101 and the dummy gate pattern 102, at an area of the wider gap shown in FIG. 7, so that pattern density of gate patterns is kept uniform. Since N-channel type MOS transistors are assumed to be used in FIG. 8A, the dummy gate pattern 103 is controlled to be ON. However, its on-resistance is large, which is several kΩ per μm, thereby causing a decrease in speed of circuit operation.

FIG. 8B shows a cross-sectional diagram of FIG. 8A along the B-B′ line. As shown in FIG. 8B, a first conductive region 110 having p-type doping is formed in the diffusion layer 100, a second conductive region 111 having n-type doping is formed on the first conductive region 110, and an insulation film 112 is formed on the second conductive region 111. A MOS transistor is formed under the dummy gate pattern 103 similarly as the gate pattern 101. The MOS transistor at the dummy gate pattern 103 turns on when a high potential is applied to the dummy gate pattern 103. However, the on-resistance of the MOS transistor is higher than the resistance of the diffusion layer 100, and thus it is inevitable that the resistance becomes higher.

As described above, according to the conventional layout methods of the semiconductor device, it is difficult to achieve both an improvement in dimensional accuracy and a high-speed circuit operation while maintaining uniform pattern density of gate patterns of MOS transistors by utilizing dummy gate patterns.

### SUMMARY

The present invention seeks to solve the above problems and provides a semiconductor device capable of improving dimensional accuracy by arranging a gate pattern and a dummy gate pattern to obtain uniform pattern density.

In one of aspects of the invention, there is provided a semiconductor device having dummy gate pattern, the semiconductor device includes a diffusion layer formed on a semiconductor substrate, a gate pattern arranged over the diffusion layer and functioning as a gate electrode of a MOS transistor, and a dummy gate pattern arranged adjacently to the gate pattern with a constant gap over the diffusion layer and not functioning as the gate electrode. In the semiconductor device of the present invention, the dummy gate pattern is disconnected at a predetermined position in a gate width direction over the diffusion layer.

According to the aspects of the invention, when forming the MOS transistor on the diffusion layer, the actual gate pattern and the dummy gate pattern are adjacently arranged with the constant gap, and distribution of density of gate patterns can be kept uniform regardless of channel size, thereby improving dimensional accuracy. Since the dummy gate pattern is disconnected at the predetermined position, resistance of the diffusion layer under a cut portion is smaller than on-resistance of the MOS transistor, and thus high-speed operation of the MOS transistor can be achieved.

As described above, according to the present invention, since the gate pattern and the dummy gate pattern are adjacently arranged with a predetermined gap and the dummy gate pattern is disconnected at a predetermined position, dimensional accuracy can be improved by keeping uniform distribution of density of gate patterns. Additionally, resistance of the diffusion layer under the cut portion can be sufficiently reduced, so that high-speed operation of the MOS transistor can be achieved.

### BRIEF DESCRIPTION OF THE DRAWINGS

The above featured and advantages of the present invention will be more apparent from the following description of certain preferred embodiments taken in conjunction with the accompanying drawings, in which:

FIG. 1A is a plane view showing a layout of a semiconductor device of a first embodiment of the present invention;

FIG. 1B is a cross-sectional diagram of FIG. 1A along the A-A′ line;

FIG. 2 is a plane view showing a layout of a semiconductor device of a second embodiment of the present invention;

FIG. 3 is a diagram showing a circuit configuration of a precharge balance circuit implemented in a DRAM of a third embodiment;

FIG. 4 is a plane view showing a layout corresponding to the precharge balance circuit of FIG. 3 in the third embodiment.

FIG. 5 is a plane view showing a layout without a dummy gate pattern 13 of the present invention as a comparison example explaining an effect of FIG. 4;

FIG. 6 is a plane view showing a modification of the layout of FIG. 4 in the third embodiment;

FIG. 7 is a diagram showing a layout example of a conventional dummy gate pattern;

FIG. 8A is a diagram showing another layout example of the conventional dummy gate pattern; and

FIG. 8B is a cross-sectional diagram of FIG. 8A along the B-B′ line.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes. In the following, three embodiments having different structures and effects will be described.

### First Embodiment

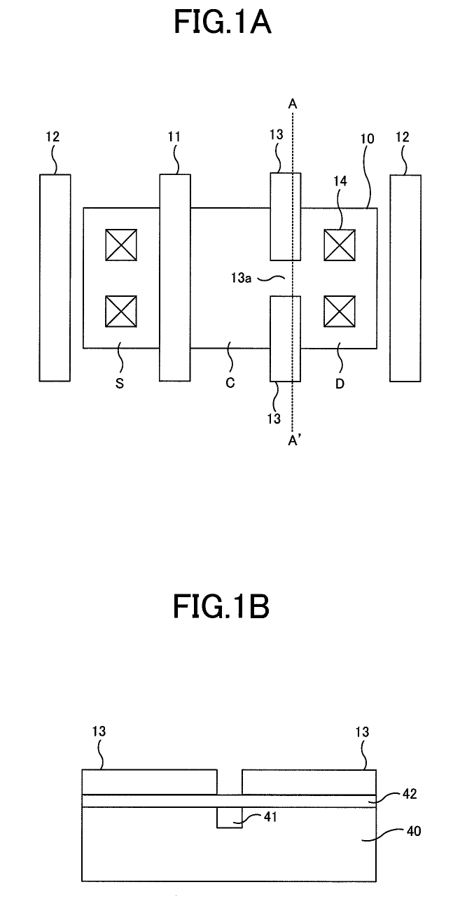

FIG. 1A is a plane view showing a layout of a semiconductor device of a first embodiment of the present invention. In FIG. 1A, there are shown a diffusion layer 10 formed on a semiconductor substrate to form MOS transistors, a gate pattern 11 formed over the diffusion layer 10, general dummy gate patterns 12, a dummy gate pattern 13 which is unique to the present invention, a drain region D and a source region S formed on both sides inside the diffusion layer 10, and contacts 14 formed on the drain and source regions D and S.

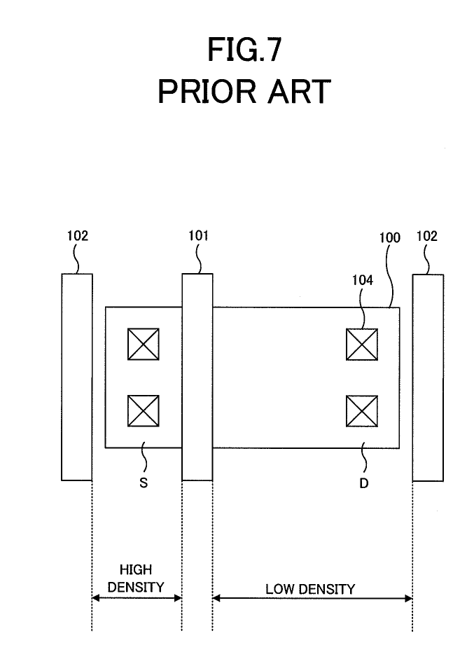

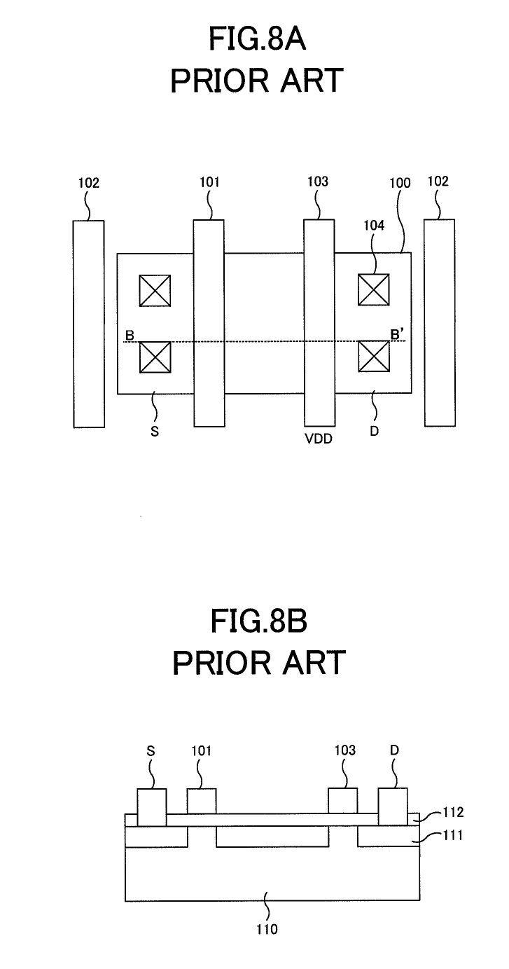

The dummy gate patterns 12 are formed over both side regions not overlapping the diffusion layer 10 in the same manner as in FIG. 7, the gate pattern 11 is formed over the vicinity of the source region S, and the dummy gate pattern 13 is formed over the vicinity of the drain region D. As shown in FIG. 1A, a group of patterns including the gate pattern 11, the dummy gate patterns 12 of both sides and the dummy gate pattern 13 is arranged in parallel with a constant gap between adjacent patterns, so that distribution of density of the group of patterns is kept uniform. Further, the gate pattern 11 and the dummy gate patterns 12 and 13 are formed using polysilicon pattern having the same line width. In addition, the line width of the respective patterns is shorter than the above constant gap. By this arrangement, dimensional accuracy of the gate patterns is improved, and the channel size of the MOS transistors is kept stable.

Each of the gate pattern 11 and the dummy gate patterns 12 is formed continuously in a longitudinal direction of FIG. 1A, while the dummy gate pattern 13 is disconnected at a cut portion 13a near the center, thereby being divided into two pattern portions. A central region C is sandwiched between the gate pattern 11 and the dummy gate pattern 13, and a potential of the drain region D is supplied to the central region C through the cut portion 13a in the diffusion layer 10. Generally, resistance of the diffusion layer 10 is several tens Ω, which is smaller than on-resistance of the MOS transistor by two digits. Thus, by forming the cut portion 13a, the resistance under the cut portion 13a between the drain region D and the central region C can be sufficiently reduced. In the first embodiment, it is possible to connect the drain region D and the central region C by using a lower resistance, in comparison with a structure in which a continuous (not disconnected) dummy gate pattern is arranged between the drain region D and the central region C.

In FIG. 1A, the dummy gate pattern 13 is desired to be in a floating state while not being connected to a power supply voltage or the like. When the potential of the dummy gate pattern 13 is in a floating state, fringe capacitance between the dummy gate pattern 13 and the drain region D is reduced, and therefore it is effective for higher-speed circuit operation and suppression of operation current. A general MOS transistor has the fringe capacitance equivalent to, for example, about one-third of bottom capacitance of a diffusion layer, however when employing the first embodiment, influence of the fringe capacitance can be suppressed near the dummy gate pattern 13.

In addition, if the length of the cut portion 13a in a gate width direction (a gap between two pattern portions of the dummy gate pattern 13) is extended, the width of the region between the drain region D and the central region C is increased, thereby reducing the above-mentioned resistance. However, if the length of the cut portion 13a in the gate width direction is extended, fluctuation of the channel width in the vicinity thereof affects transistor characteristics. Therefore, it is desirable to set a proper size of the cut portion 13a depending on a trade-off between the resistance and the transistor characteristics. Further, each pattern portion of the dummy gate pattern 13 is desired to be formed so that its length overlapping the diffusion layer 10 in the gate width direction is longer than the line width of the dummy gate pattern 13.

Each of the contacts 14 over the source region S and the contacts 14 over the drain region D extends to an upper wiring layer (not shown) so as to be connected to a predetermined wiring, and current flows through the contacts 14 between source and drain of the MOS transistor. Here, FIG. 1A shows an example in which the gate pattern 11 is formed over the vicinity of the source region S and the dummy gate pattern 13 is formed over the vicinity of the drain region D, however formations thereof can be replaced with each other so that the dummy gate pattern 13 is formed over the vicinity of the source region S and the gate pattern 11 is formed over the vicinity of the drain region D.

FIG. 1B shows a cross-sectional diagram of FIG. 1A along the A-A′ line. As shown in FIG. 1B, a first conductive region 40 having p-type doping is formed under the dummy gate pattern 13 via an insulation film 42, and a second conductive region 41 having n-type doping is formed under the cut portion 13a via the insulation film 42. The central region C and the drain region D are electrically connected to each other through the second conductive region 41, so that the resistance therebetween can be reduced.

### Second Embodiment

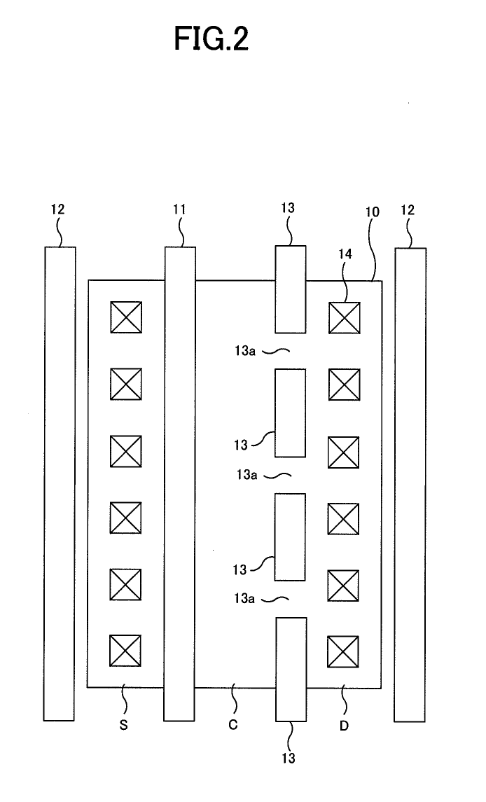

FIG. 2 is a plane view showing a layout of a semiconductor device of a second embodiment of the present invention. In FIG. 2, there are shown the diffusion layer 10, the gate pattern 11, the general dummy gate patterns 12, the dummy gate pattern 13 which is unique to the present invention, the drain region D and the source region S formed on both sides inside the diffusion layer 10, and the contacts 14 formed on the drain and source regions D and S, like in FIG. 1. However the size of FIG. 2 is enlarged in a gate width direction relative to FIG. 1A. Therefore, in the arrangement of FIG. 2, the number of the contacts 14 connected to MOS transistors is three times that of FIG. 1A.

The gate pattern 11 and the dummy gate patterns 12 are arranged in the same manner as in FIG. 1A, while the dummy gate pattern 13 is disconnected and divided into four pattern portions by three cut portions 13a. The respective cut portions 13a have the same shape (size) as that of FIG. 1A, and adjacent cut portions 13a are arranged with a constant gap. In this manner, by increasing the division number of the dummy gate pattern 13, the resistance between the drain region D and the central region C can be further reduced.

The division number of the dummy gate pattern 13 and positions of the cut portions 13a can be set without being limited to the arrangement of FIG. 2. If the division number of the dummy gate pattern 13 is increased, the resistance between the drain region D and the central region C can be reduced, but the length of each pattern portion of the dummy gate pattern 13 in the gate width direction is correspondingly shortened, and there may be a risk of dispersion of resist in manufacturing process. Thus, the appropriate division number of the dummy gate pattern 13 is desired to be set within a range in which the degree of the dispersion of resist is allowable.

In addition, each pattern portion of the dummy gate pattern 13 is desired to be formed in a rectangle having long sides in a gate width direction and short sides in a gate length direction. This condition is a limitation of the division number of the dummy gate pattern 13 as described above.

### Third Embodiment

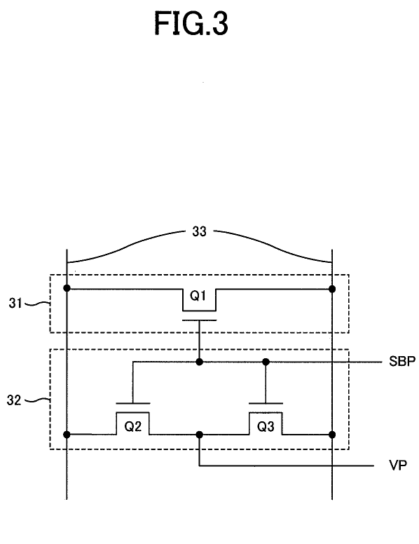

A third embodiment of the present invention will be described with reference to FIGS. 3 to 6. In the third embodiment, a case will be described in which the present invention is applied to a layout used for a precharge balance circuit implemented in a DRAM (Dynamic Random Access Memory) as a semiconductor device.

FIG. 3 shows a circuit configuration of the precharge balance circuit, which is required for a precharge operation for a pair of I/O lines of the DRAM. The precharge balance circuit shown in FIG. 3 includes a balancer 31 composed of an NMOS transistor Q1, and a precharger 32 composed of NMOS transistors Q2 and Q3, and a pair of I/O lines 33 for transmitting data is connected to the balancer 31 and the precharger 32.

A balance precharge signal SBP is applied to each gate of the NMOS transistors Q1, Q2 and Q3 of the balancer 31 and the precharger 32. The NMOS transistor Q1 of the balancer 31 is connected between the pair of I/O lines 33, and operates to balance both potentials. Further, the NMOS transistors Q2 and Q3 of the precharger 32 is connected in series between the pair of I/O lines 33, and a precharge voltage VP is supplied to commonly connected sources thereof. The NMOS transistors Q2 and Q3 operate to precharge the pair of I/O lines 33 to the precharge voltage VP.

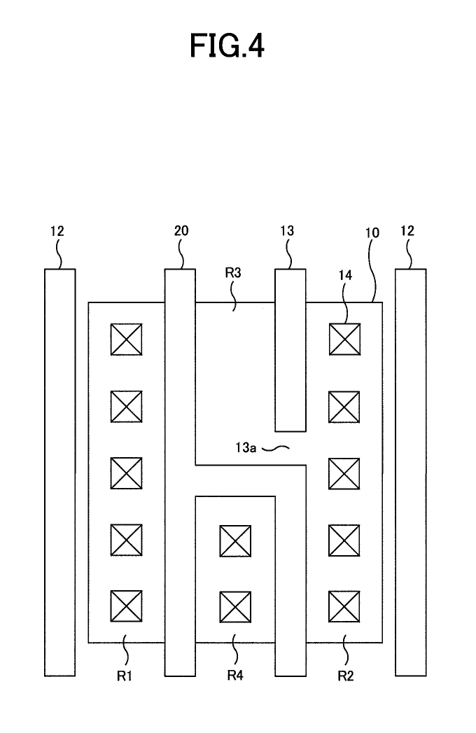

FIG. 4 is a plane view of a layout corresponding to the precharge balance circuit of FIG. 3. In FIG. 4, the diffusion layer 10 in which the above NMOS transistors Q1, Q2 and Q3 are formed, the dummy gate patterns 12, 13 and the contacts 14 are shown like in FIG. 1A, and a gate pattern 20 branching into two paths is also shown. FIG. 4 indicates four regions R1, R2, R3 and R4 partitioned by the dummy gate pattern 13 and the gate pattern 20 in the diffusion layer 10.

In the diffusion layer 10, the balancer 31 (N MOS transistor Q1) corresponds to the upper side of FIG. 4, and the precharger 32 (N MOS transistors Q2 and Q3) corresponds to the lower side of FIG. 4. One line (not shown) of the pair of I/O lines 33 is arranged over the region R1 and the other line (not shown) thereof is arranged over the region R2. The gate pattern 20 is connected to the precharge voltage VP, and functions as each gate electrode of N MOS transistors. In the center of the diffusion layer 10, the region R3 for the balancer 31 is connected to the region R2 through the cut portion 13a (open portion), like in FIG. 1A. Meanwhile, the region R4 for the precharger 32 is surrounded by the gate pattern 20 branching into two paths, and functions as common sources of the N MOS transistors Q2 and Q3. The contacts 14 formed on the region R4 are connected to a wiring (not shown) of the balance precharge signal VP, in an upper wiring layer.

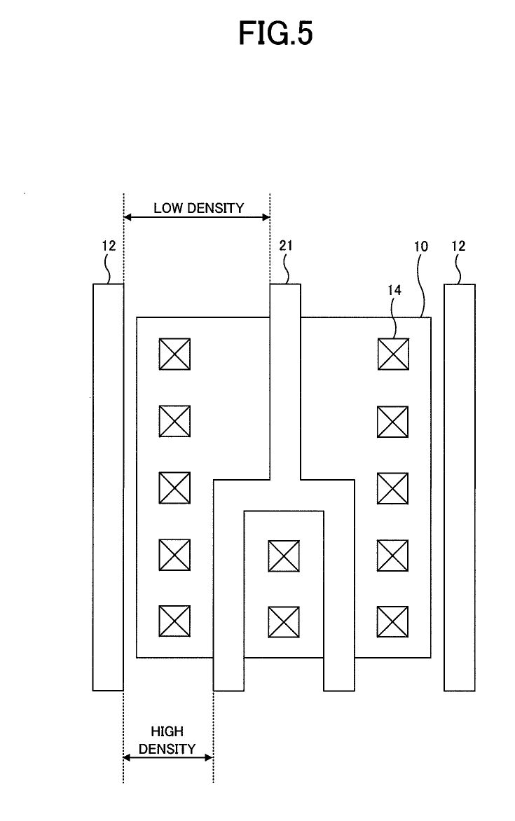

Here, FIG. 5 shows a plane view as a comparison example, which shows a layout without the dummy gate pattern 13 of the present invention, for the purpose of explaining the effect of the layout of FIG. 4. In the comparison example of FIG. 5, a gate pattern 21 branching into two paths is arranged at the center of the diffusion layer 10 on the side of the balancer 31, as different from FIG. 4. The portion of the gate pattern 21 on the side of the precharger 32 is arranged like in FIG. 4, however the dummy gate pattern 13 of FIG. 4 does not exist on the side of the balancer 31 so that the gate pattern 21 is arranged near the center. Thus, since distribution of density of gate patterns is not uniform, the gate patterns are arranged with a wider gap on the side of the balancer 31 while arranged with a narrow gap on the side of the precharger 32. In this manner, the pattern density of gate patterns is nonuniform in the layout of FIG. 5, and the pattern density of gate patterns is kept uniform in the layout of FIG. 4, thereby obtaining improved characteristics of MOS transistors in FIG. 4, relative to FIG. 5.

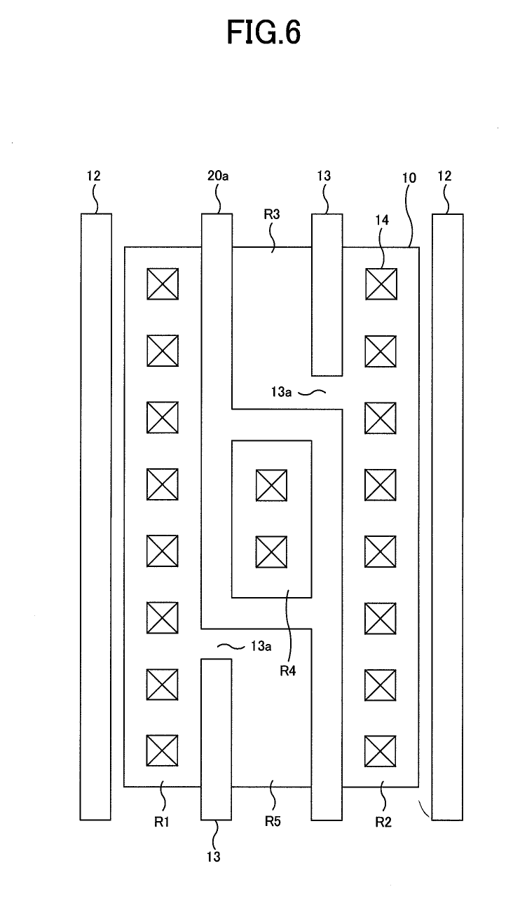

FIG. 6 is a plane view showing a modification of the layout of FIG. 4. FIG. 6 corresponds to the precharge balance circuit of FIG. 3, and differs from FIG. 4 in that a gate pattern 20a branches (converges) at two points, and two dummy gate patterns 13 are formed on both sides of the gate pattern 20a. In the layout shown in FIG. 6, both sides inside the diffusion layer 10 are arranged symmetrically with respect to the center point. In FIG. 6, the diffusion layer 10 is expanded in a gate width direction, and the number of contacts 14 is larger than that of FIG. 4. Then, balancers 31 are formed on upper and lower sides of FIG. 4, and the precharger 32 is formed on a central portion sandwiched by the balancers 31. The diffusion layer 10 is partitioned into regions including the four regions R1, R2, R3 and R4 similarly as in FIG. 4 and a region R5. One dummy gate pattern 13 is arranged between the region R2 and the region R3, the other dummy gate pattern 13 is arranged between the region R1 and the region R5, and the respective dummy gate patterns 13 are connected via cut portions (open portions) 13a.

In the layout shown in FIG. 6, the pair of I/O lines 33 includes one line over the region R1 and the other line over the region R2, which are arranged symmetrically with respect to the gate pattern 20a and the dummy gate pattern 13. That is, since each cut portion 13a exists in the vicinity of each line of the pair of I/O lines 33 and has the same shape of each line, the lines are evenly affected in the regions R1 and R2. Thereby, excellent transmittance characteristics of the pair of I/O lines 33 can be obtained.

As described above, by employing the layouts of the above embodiments, it is possible to solve the problem of dimensional accuracy which is caused by nonuniformity of the pattern density of gate patterns in the semiconductor device, and to obtain excellent transistor characteristics by achieving high-speed operation of MOS transistors formed in the diffusion layer 10. The layouts of the above embodiments can be applied to, for example, a DRAM as the semiconductor device. A general DRAM is provided with an array portion (a redundancy circuit for saving faulty is included) in which a large number of memory cells are repeatedly arranged and a peripheral portion arranged around the array portion. In particular, it is effective to apply the layouts of the above embodiments to the peripheral portion of the DRAM.

It is apparent that the present invention is not limited to the above embodiments, but may be modified and changed without departing from the scope and spirit of the invention.

What is claimed is:

1. A semiconductor device having dummy gate pattern, comprising:
a diffusion layer formed on a semiconductor substrate;
a gate pattern arranged over the diffusion layer and functioning as a gate electrode of a MOS transistor; and
a dummy gate pattern arranged adjacently to the gate pattern with a constant gap over the diffusion layer and not functioning as the gate electrode,
wherein the dummy gate pattern is disconnected at a predetermined position in a gate width direction over the diffusion layer.

2. The semiconductor device according to claim 1, wherein a plurality of patterns including the gate pattern and the dummy gate pattern are formed with a constant line width and arranged in parallel to each other with the constant gap.

3. The semiconductor device according to claim 1, wherein each of pattern portions disconnected at the predetermined position of the dummy gate pattern is formed in a rectangle having long sides in a gate width direction and short sides in a gate length direction.

4. The semiconductor device according to claim 3, wherein a length of a cut portion of the dummy gate pattern in a gate width direction is shorter than the constant gap.

5. The semiconductor device according to claim 1, wherein the dummy gate pattern is controlled to be in a floating state.

6. The semiconductor device according to claim 1, wherein drain and source regions are formed in the diffusion layer, and the gate pattern is formed in a vicinity of one of the regions while the dummy gate pattern is formed in a vicinity of the other of the regions.

7. The semiconductor device according to claim 1, wherein the dummy gate pattern is disconnected at a plurality of positions in a gate width direction over the diffusion layer.

8. The semiconductor device according to claim 1, wherein the gate pattern branching into pattern portions are arranged in a region where the dummy gate pattern is not arranged, and the pattern portions branched from the gate pattern are arranged adjacently to one another with the constant gap.

9. The semiconductor device according to claim 8, wherein a plurality of the MOS transistors included in a precharge balance circuit required for a precharge operation of a semiconductor memory are formed on the diffusion layer.
